(19) United States
(12) Patent Application Publication
(10) Pub. No.: US 2009/0095509 A1
(43) Pub. Date: Apr. 16, 2009

(54) CORE SUBSTRATE AND METHOD OF PRODUCING THE SAME

(75) Inventors: Shin Hirano, Kawasaki (JP); Kenji Iida, Kawasaki (JP); Yasutomo Maehara, Kawasaki (JP); Tomoyuki Abe, Kawasaki (JP); Takashi Nakagawa, Kawasaki (JP); Hideaki Yoshimura, Kawasaki (JP); Seigo Yamawaki, Kawasaki (JP); Norikazu Ozaki, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/188,736

(22) Filed: Aug. 8, 2008

(30) Foreign Application Priority Data
Oct. 12, 2007 (JP) 2007-267140

(51) Int. Cl. H05K 1/00; H05K 3/10

(52) U.S. Cl. 174/250; 29/846

(57) ABSTRACT

In the core substrate, short circuit between an electrically conductive core section and a plated through-hole section can be securely prevented and cables can be formed in a high dense state. The core substrate comprises: the electrically conductive core section having a pilot hole, through which the plated through-hole section is formed; cable layers being respectively laminated on the both side faces of the core section; a plated layer coating an inner face of the pilot hole; and an insulating material filling a space between the plated layer and an outer circumferential face of the plated through-hole section.

### BACKGROUND OF THE INVENTION

The present invention relates to a core substrate having an electrically conductive core section, a method of producing the core substrate and a circuit board including the core substrate, more precisely relates to a core substrate, in which a plated through-hole section is formed, a method of producing the core substrate and a circuit board including the core substrate.

Some test substrates, which are used for testing circuit boards, on which semiconductor elements will be mounted, and semiconductor wafers, include core substrates composed of carbon fiber-reinforced plastic (CFRP). In comparison with conventional glass-epoxy core substrates, thermal expansion coefficients of the core substrates composed of carbon fiber-reinforced plastic are small, and thermal expansion coefficients of the circuit boards having such core substrates can be corresponded to those of semiconductor elements to be mounted on the circuit boards. Therefore, thermal stress generated between a semiconductor element and a circuit board can be effectively avoided.

The circuit board is formed by laminating cable layers on the both side faces of the core substrate, and plated through-hole (PTH) sections are formed in the core substrate so as to mutually electrically connect the cable layers on the both side faces thereof. The plated through-hole sections are formed by boring through-holes in a substrate and forming plated layers (electrically conductive parts) on inner faces of the through-holes.

In case of the core substrate having the electrically conductive core section composed of, for example, carbon fiber-reinforced plastic, if the plated through-hole sections are formed by merely boring the through-holes and plating the inner faces thereof, the plated through-hole sections and the core section are electrically shorted. Thus, the plated through-hole sections are formed in the core substrate having the electrically conductive core section by the steps of: forming pilot holes, whose diameters are greater than those of the plated through-hole sections to be formed, in the core substrate; filling the pilot holes with insulating resin; and forming the plated through-hole sections in the filled through-holes. With this method, the plated through-hole sections and the core section are not electrically shorted (see JP Kohyo Gazette No. 2004/064467, JP Patent Gazette No. 2006-222216).

However, if the pilot holes are drilled, burrs are formed on inner faces of the pilot holes and the plated through-hole sections and the core section will be electrically shorted. To solve this problem, the inner faces of the pilot holes are coated with insulating layers so as not to electrically short the plated through-holes and the core section (see JP Patent Gazette No. 2006-222216). However, it is difficult to perfectly coat the rough inner faces of the pilot holes.

Further, these days, densities of cable layers have been highly increased, diameters of the plated through-hole sections have been highly reduced, and separations between the plated through-hole sections and the inner faces of the pilot holes have been highly shortened. Therefore, the plated through-hole sections and the core section are easily electrically shorted.

### SUMMARY OF THE INVENTION

The present invention was conceived to solve the above described problems.

An object of the present invention is to provide a core substrate, in which short circuit between an electrically conductive core section and a plated through-hole section can be securely prevented and cables can be formed in a high dense state.

Another object is to provide a method of producing said core substrate.

Further object is to provide a circuit board having said core substrate.

To achieve the objects, the present invention has following constitutions.

Namely, the core substrate of the present invention comprises: an electrically conductive core section having a pilot hole, through which a plated through-hole section is formed; cable layers being respectively laminated on the both side faces of the core section; a plated layer coating an inner face of the pilot hole; and an insulating material filling a space between the plated layer and an outer circumferential face of the plated through-hole section.

The core substrate may further comprise an insulating film coating the plated layer, which coats the inner face of the pilot hole. With this structure, the short circuit between the electrically conductive core section and the plated through-hole section can be further securely prevented.

In the core substrate, the plated layer may make the inner face of the pilot hole smooth. With this structure, the pilot hole can be filled without forming voids in the resin, so that the short circuit between the electrically conductive core section and the plated through-hole section can be effectively prevented.

In the core substrate, the plated layer may encompass electrically conductive accretions stuck on the inner face of the pilot hole. With this structure, invasion of the conductive accretions, e.g., carbon dusts, which are formed by, for example, drilling the pilot hole and stuck on the inner face of the pilot hole, into the insulating material can be effectively prevented, so that the short circuit between the electrically conductive core section and the plated through-hole section can be effectively prevented.

Preferably, the core section is composed of carbon fiber-reinforced plastic and formed into a flat plate by heating and pressurizing a plurality of prepregs including carbon fibers.

The method of producing the core substrate of the present invention comprises the steps of: forming a pilot hole in a substrate having an electrically conductive core section; forming a plated layer on an inner face of the pilot hole; filling the pilot hole, in which the plated layer has been formed, with an insulating material; forming a through-hole in the pilot hole, which has been filled with the insulating material; and forming a plated layer on an inner face of the through-hole so as to form a plated through-hole section.

Note that, the pilot hole may be formed in the core section by a drill, but the present invention is not limited to the drill. Other suitable means for forming hole may be employed to form the pilot hole.

In the method, cable layers may be integrally formed on the both side faces of the substrate after filling the pilot hole with the resin, and the through-hole, which passes through the pilot hole, is formed in the substrate, on which the cable layers have been integrally formed.

In the method, an insulating film may be formed on the plated layer by an electrodeposition process, in which the plated layer is used as an electric power feeding layer, after forming the plated layer on the inner face of the through-hole by plating the substrate having the pilot hole. With this method, the short circuit between the electrically conductive core section and the plated through-hole section can be properly prevented in a circuit board.

In the method, a plated layer, which makes the inner face of the pilot hole smooth, may be formed when the substrate having the pilot hole is plated, or a plated layer, which encompasses electrically conductive accretions stuck on the inner face of the pilot hole, may be formed when the substrate having the pilot hole is plated. With this method, forming voids in the insulating material can be effectively prevented when the pilot hole is filled with the insulating material. Further, peeling the conductive accretions from the inner face of the pilot hole can be effectively prevented, so that the short circuit between the electrically conductive core section and the plated through-hole section can be prevented.

In the method, the core section may be formed into a flat plate by the steps of: laminating a plurality of prepregs including carbon fibers; and heating and pressurizing the laminated prepregs.

Further, the multi-layered circuit board of the present invention comprises: a core substrate including an electrically conductive core section having a pilot hole, through which a plated through-hole section is formed, cable layers being respectively laminated on the both side faces of the core section, a plated layer coating an inner face of the pilot hole, and an insulating material filling a space between the plated layer and an outer circumferential face of the plated through-hole section; and a cable layer being laminated on the core substrate.

In the core substrate of the present invention, the inner face of the pilot hole, through which the plated through-hole section is pierced, is coated with the plated layer, thereby forming voids can be prevented when the pilot hole is filled with the insulating material and the short circuit between the electrically conductive core section and the plated through-hole section can be prevented. Even if electrically conductive accretions are stuck on the inner face of the pilot hole, the plated layer prevents the conductive accretions from peeling off from the inner face of the pilot hole, so that mixing the conductive accretions with the insulating material, which fills the pilot hole, can be prevented. Therefore, insulation performance of the insulating material can be maintained, and the short circuit between the electrically conductive core section and the plated through-hole section, which is caused by the conductive accretions, can be prevented.

### BRIEF DESCRIPTION OF THE DRAWINGS

Embodiments of the present invention will now be described by way of examples and with reference to the accompanying drawings, in which:

FIGS. 1A-1D are partial sectional views showing the steps of processing a substrate, in which pilot holes are formed in a substrate and the pilot holes are filled with resin;

FIGS. 2A-2C are partial sectional views showing the steps of processing the substrate, in which insulating films are formed in the pilot holes and the pilot holes are filled with the resin;

FIGS. 3A-3C are partial sectional views showing the steps of producing the core substrate; and

FIGS. 4A-4C are partial sectional views showing the further steps of producing the core substrate;

FIG. 5 is a partial sectional view of another core substrate;

FIGS. 6A and 6B are partial sectional views showing the steps of producing a circuit board; and

FIG. 7 is a partial sectional view of another circuit board.

### DETAILED DESCRIPTION OF THE EMBODIMENTS

Preferred embodiments of the present invention will now be described in detail with reference to the accompanying drawings.

### (Steps of Forming Pilot Holes)

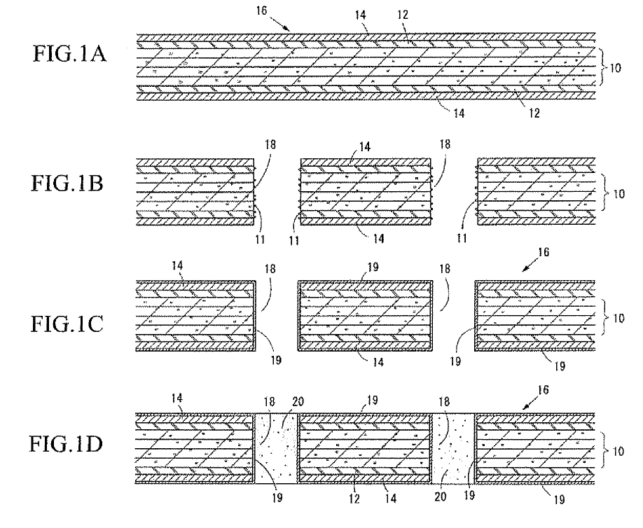

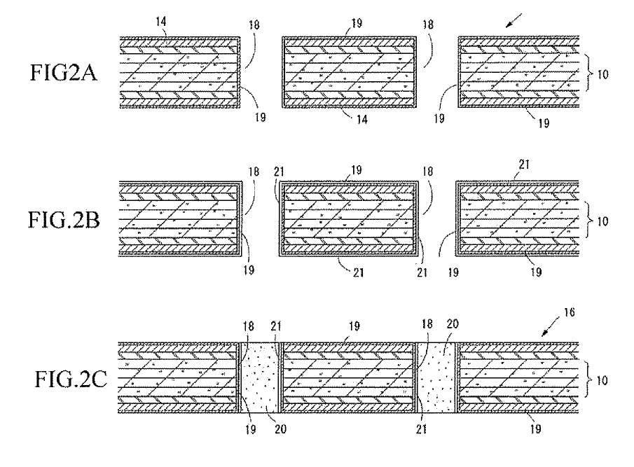

FIGS. 1A-2C show the steps of processing a substrate, wherein pilot holes, in which plated through-hole sections will be formed, are formed in the substrate and the pilot holes are filled with insulating materials.

FIG. 1A shows a flat plate-shaped substrate 16, which comprises a core section 10 composed of carbon fiber-reinforced plastic and copper foils 14 respectively bonded on the both side faces of the core section 10 with prepregs 12. The core section 10 is formed by the steps of: laminating four prepregs, each of which is formed by impregnating a carbon cloth with polymer, e.g., epoxy resin; and heating and pressurizing the laminated prepregs so as to integrate them. Note that, number of the laminated prepregs including carbon fibers, which constitute the core section 10, can be optionally selected.

In the present embodiment, the core section 10 is constituted by woven carbon fiber cloths, each of which is composed of carbon fiber filaments. Further, unwoven carbon fiber cloths, carbon fiber meshes, etc. may be used instead of the woven carbon fiber cloth. Thermal expansion coefficients of carbon fibers are about 0 ppm/° C., and a thermal expansion coefficient of the core section 10 can be adjusted by selecting a rate of content of carbon fibers in the carbon fiber-reinforced plastic, resin materials included in the carbon fibers, fillers mixed with the resin, etc. In the present embodiment, the thermal expansion coefficients of the core section 10 is about 1 ppm/° C.

A thermal expansion coefficient of the entire core substrate having the core section 10 composed of the carbon fiber-reinforced plastic can be adjusted by selecting thermal expansion coefficients of cable layers, which constitute the core substrate, and insulating layers, which are provided between the cable layers. Further, a thermal expansion coefficient of a circuit board, which is formed by laminating build-up layers on the both side faces of the core substrate, can be properly adjusted by selecting thermal expansion coefficients of the core substrate and the build-up layers. Thermal expansion coefficients of semiconductor elements are about 3.5 ppm/° C. Thermal expansion coefficients of the circuit board can be easily corresponded to that of semiconductor elements to be mounted on the circuit board.

In FIG. 1B, pilot holes 18 are bored in the substrate 16. The pilot holes 18 are through-holes, which are bored in the thickness direction of the substrate 16 by a drill. Diameters of the pilot holes are greater than those of through-holes of plated through-hole sections, which will be formed in the following step. In the present embodiment, the diameters of the pilot holes 18 are 0.8 mm; the diameters of the through-holes of the plated through-hole sections are 0.35 mm. The pilot holes 18 are located at prescribed planar positions, which correspond to the plated through-hole sections to be formed in the core substrate.

When the pilot holes 18 are drilled, burrs are formed on inner faces of the pilot holes 18 by, for example, abrasion of the drill, and the pilot holes 18 have rough or uneven inner faces. Further, drill dusts of the core section 10 will stick on the inner faces of the pilot holes 18.

In case of the core section 10 composed of carbon fiber-reinforced plastic, carbon dusts stick on the inner faces of the pilot holes 18. The carbon dusts 11 have electric conductivity, so if the carbon dusts 11 invade into resin 20 filling the pilot holes 18, the insulation performance of the resin 20 is worsened. Further, the plated through-hole section and the core section 10 will be electrically shorted.

To solve this problem, in the present embodiment, electroless copper plating and electrolytic copper plating are performed in this order after forming the pilot holes 18 in the substrate 16 so as to coat the inner faces of the pilot holes 18 with plated layers 19. By electroless-plating the substrate 16 with copper, the copper layer is formed on the entire inner faces of the pilot holes 18 and the entire side faces of the substrate 16. Then, the electrolytic plating is performed with using the copper layer as an electric power feeding layer, so that the plated layers 19 can be formed on the inner faces of the pilot holes 18 and the both side faces of the substrate 16. A thickness of the copper layer formed by the electroless plating is about 0.5 μm; thicknesses of the plated layers 19 formed by the electrolytic plating are about 10-20 μm.

Purposes of plating the substrate 16 and coating the inner faces of the pilot holes 18 are to make the inner faces of the pilot holes 18, which have been roughened by the drilling process, smooth and not to peel the dusts 11 from the inner faces of the pilot holes 18. Therefore, thicknesses of the plated layers 19 may be designed to make the inner faces of the pilot holes smooth and to encompass or embed the dusts 11.

By electroless-plating and electrolytic-plating the substrate 16 with copper, the entire inner faces of the pilot holes 18 can be securely coated with the plated layers 19.

In FIG. 1D, the pilot holes 18 are filled with the resin 20. The pilot holes 18 can be filled with resin 20 by screen-printing or using a metal mask. After filling the pilot holes 18 with the resin 20, the resin 20 is cured by a heating process. After heat-curing the resin 20, ends of the resin 20, which are projected outward from the pilot holes 18, are abraded and flattened, so that end faces of the cured resin 20 are made level with the surfaces of the substrate 16 (the surfaces of the plated layers 19).

The resin 20 for filling the pilot holes 18 is an insulating material. Many kinds of insulating materials may be employed. In the present embodiment, the insulating material is thermosetting epoxy resin.

In the present embodiment, the substrate 16 is plated so as to coat the inner faces of the pilot holes 18 with the plated layers 19 before filling the pilot holes 18 with the resin 20. Therefore, no dusts 11 stuck on the inner faces of the pilot holes 18 are mixed with the resin 20, so that insulating performance of the resin 20 can be secured.

By plating the inner faces of the pilot holes 18, the inner faces of the pilot holes 18 become smooth faces, so that wetness of the resin 20 with respect to the plated layers 19 is improved. Therefore, the resin 20 can be smoothly introduced into the pilot holes 18 without forming voids in the resin 20.

If the inner faces of the pilot holes 18 are roughened, air will be easily mixed with the resin 20 and voids will be formed therein. When plated through-hole sections are formed in the following step, the voids make the plated through-hole sections communicate with the core section, thereby the plated through-hole sections and the core section will be electrically shorted. By coating the inner faces of the pilot holes 18 with the plated layers 19, forming voids in the resin 20 can be prevented and the short circuit between the core section and the plated through-hole section can be effectively prevented.

FIGS. 2A-2C show another production steps, wherein insulating films 21 are formed on the inner faces of the pilot holes 18, by an electrodeposition method, after performing the plating step shown in FIG. 1C.

In FIG. 2A, the substrate 16 is plated, so that the inner faces of the pilot holes 18 and the both side faces of the substrate 16 are coated with the plated layers 19.

In FIG. 2B, the insulating films 21 are formed on the inner faces of the pilot holes 18 and the surfaces of the substrate 16 by the electrodeposition method. The plated layers 19 entirely coat the inner faces of the pilot holes 18 and the both side faces of the substrate 16. Therefore, the insulating films 21 can be formed on the inner faces of the pilot holes 18 and the entire side faces of the substrate 16 by the electrodeposition method, in which the plated layers 19 are used as electric power feeding layers. For example, the insulating films 21 can be electrodeposited by a constant current method, in which the substrate is soaked in an electrodeposition solution of epoxy resin and then a direct current is passed through the plated layers 19. After electrodepositing the insulating films 21 on the inner faces of the pilot holes 18 and the both side faces of the substrate 16, a drying process and a heating process are performed so as to cure the insulating films 21. Thicknesses of the insulating films 21 are 10-20 μm.

In FIG. 2C, the pilot holes 18 are filled with the resin 20 after electrodepositing the insulating films 21. After filling the pilot holes 18 with the resin 20 and curing the resin 20, ends of the resin 20, which are projected outward from the pilot holes 18, are abraded and flattened. At that time, the insulating films 21 formed on the both side faces of the substrate 16 are simultaneously abraded and removed.

In the present embodiment, the insulating films 21 are formed on the inner faces of the pilot holes 18 after plating the substrate 16. Therefore, the inner faces of the pilot holes 18, which have been roughened by the drilling process, are coated with not only the plated layers 19 but also the insulating films 21, so that smoothness of the inner faces of the pilot holes 18 can be further improved. Further, the drill dusts 11 stuck on the inner faces of the pilot holes 18 can be securely covered. By improving the smoothness of the inner faces of the pilot holes 18, forming voids in the resin 20 can be prevented while filling the pilot holes 18 with the resin 20. Further, mixing the dusts 11 with the resin 20 can be prevented, so that the insulating performance of the resin 20 can be secured and the short circuit between the core section 10 and the plated through-hole sections can be effectively prevented.

In some cases, a desmear treatment is performed for the substrate 16 so as to remove contaminations from the inner faces of the pilot holes 18 after forming the pilot holes 18 in the substrate 16. By performing the desmear treatment, contaminations can be removed from inner faces of the pilot holes 18 and the surfaces of the substrate 16. However, the inner faces of the pilot holes 18 are roughened. In this case, the inner faces of the pilot holes 18 can be made smooth by forming the plated layers 19 and the insulating films 21 on the inner faces of the pilot holes 18. Further, the short circuit between the core section 10 and the plated through-hole sections can be effectively prevented.

In the above described embodiments, the pilot holes 18 are formed by the drill, but the present invention is not limited to the drill. For example, other suitable means, e.g., laser, may be employed to form the pilot holes 18. Further, the core section 10 is composed of carbon fiber-reinforced plastic, but the core section 10 may be composed of other electrically conductive materials.

### (Steps of Producing Core Substrate)

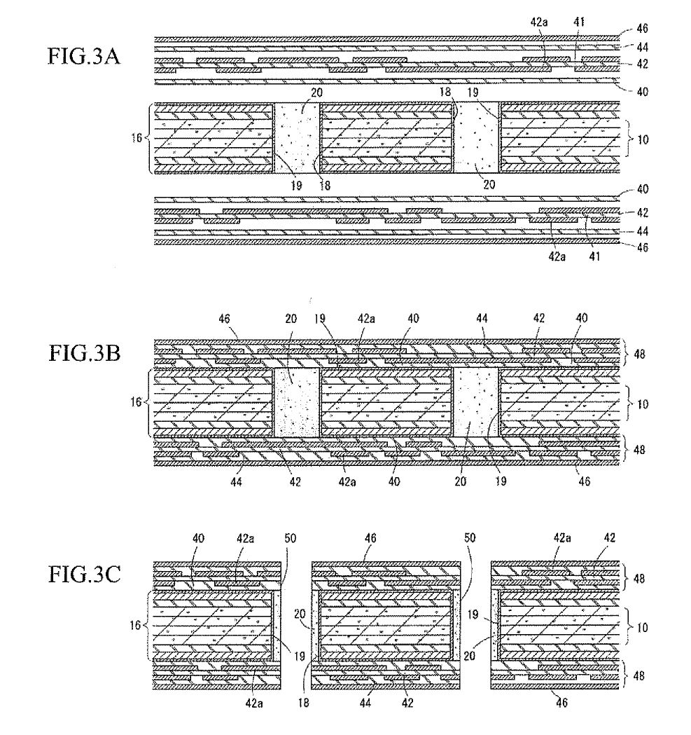

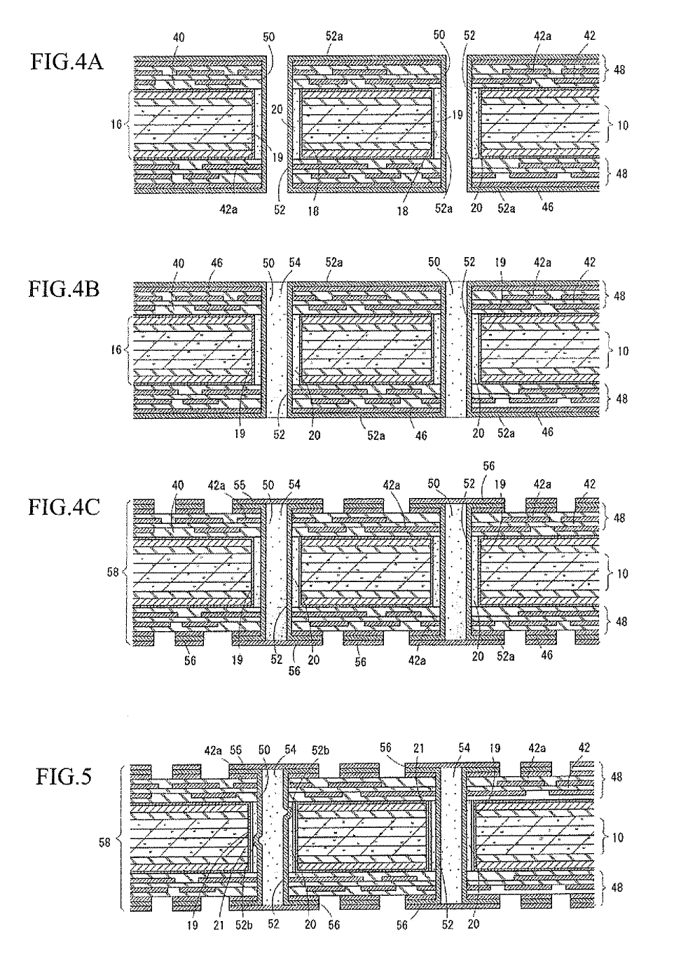

FIGS. 3A-4C show the steps of producing the core substrate, in which cable layers are formed on the both side faces of the substrate 16.

In FIG. 3A, the inner faces of the pilot holes 18 are coated with the plated layers 19, and the pilot holes 18 are filled with the resin 20. Further, prepregs 40, cable sheets 42, prepregs 44 and copper foils 46 are arranged and laminated, in this order, on the both side faces of the core member 16. Each of the cable sheets 42 is constituted by an insulating resin sheet 41 and cable patterns 42a, which are formed on the both faces of the insulating resin sheet 41. The cable sheet 42 may be formed by etching copper foil layers of a copper-bonded substrate, which is constituted by an insulating resin sheet composed of a glass cloth and copper foils bonded on the both faces of the insulating resin sheet, in prescribed patterns.

In FIG. 3B, the prepregs 40, the cable sheets 42, the prepregs 44 and the copper foils 46 are laminated, in this order, on the both side faces of the substrate 16. Then, they are heated and pressurized, so that the prepregs 40 and 44 are cured and cable layers 48 are integrally laminated on the substrate 16. The prepregs 40 and 44 are formed by impregnating glass cloths with resin, and the uncured prepregs 40 and 44 are provided between layers. By the heating and pressurizing process, the prepregs 40 and 44 insulate and integrate the cable layers 48.

Each of the cable layers 48 formed on the both side faces of the substrate 16 can be formed into a multi-layer structure. In this case, a plurality of the cable sheets 42 are laminated with the prepregs. The outermost cable patterns are formed in the surfaces of the copper foils 46 when build-up layers are formed on the both side faces of the core substrate.

In FIG. 3C, through-holes 50 are bored in the substrate 16, on which the cable layers 48 have been laminated, so as to form the plated through-hole sections. The through-holes 50 are coaxial with the pilot holes 18 and bored, by a drill, in the thickness direction of the substrate 16 integrated with the cable layers 48. Since diameters of the through-holes 50 are smaller than those of the pilot holes 18, the resin 20 is exposed in the inner faces of the through-holes 50 passing through the resin 20.

In FIG. 4A, the substrate 16 is plated with copper by an electroless plating method and an electrolytic plating method so as to form the plated through-hole sections 52 on the inner faces of the through-holes 50 after forming the through-holes 50. By performing the electroless plating method, the inner faces of the through-holes 50 and the entire surfaces of the substrate 16 are coated with copper. Then, the electrolytic plating method is performed with using the copper layers as electric power feeding layers, so that the inner faces of the through-holes 50 and the entire surfaces of the substrate 16 are coated with plated layers 52a. The plated layers 52a formed on the inner faces of the through-holes 50 acts as the plated through-hole sections 52, which mutually connect cable patterns formed on the both side faces of the substrate 16.

In FIG. 4B, the through-holes 50 are filled with insulating resin 54. For example, the insulating resin 54 is epoxy resin. The through-holes 50 can be filled with the insulating resin 54 by, for example, a screen printing method. After filling the resin 54 in the thorough-holes 50, the resin 54 is heated and cured.

In FIG. 4C, the copper foils 46 and the plated layers 52a on the both side faces of the substrate 16 are etched in prescribed patterns so as to form the core substrate 58, in which cable patterns 56 are formed on the side faces of the substrate 16. In the present embodiment, after performing the step shown in FIG. 4B, cap-plated layers 55 are formed on the side faces of the substrate 16, and then the cable patterns 56 are formed by etching the cap-plated layers 55, the plated layers 52a and the copper foils 46.

The cable patterns 56 on the both side faces of the core substrate 58 are mutually electrically connected by the plated through-hole sections 52. The cable patterns 42a formed in the cable layers 48 are electrically connected to the plated through-hole sections 52 at suitable positions.

In the method of producing the core substrate of the present embodiment, the inner faces of the pilot holes 18 are coated with the plated layers 19 by the plating method after forming the pilot holes 18, in which the plated through-hole sections 52 will be respectively formed, in the substrate 16. Therefore, the resin 20 fills a space between the inner face of each of the pilot holes 18 and an outer circumferential face of each of the through-hole sections 52, so that the through-hole sections 52 can be securely insulated from the core section 10. By encompassing or embedding the electrically conductive dusts stuck on the inner faces of the pilot holes 18 by the plated layers 19, mixing the dusts with the resin 20 can be prevented. Therefore, the insulating performance of the resin 20 can be secured, and forming voids in the resin 20 can be prevented when the pilot holes 18 are filled with the resin 20 so that short circuit between the plated through-hole sections 52 and the plated layers 19, which is caused by the voids, can be prevented.

FIG. 5 shows the core substrate 58, in which the plated layers 19 are formed on the inner faces of the pilot holes 18 by the step shown in FIG. 2C and in which the cable layers 48 are formed on the both side faces of the substrate 16 and the plated through-hole sections 52 are formed in the substrate 16 by the steps shown in FIGS. 3A-4C. The cable patterns 56 are formed on the both side faces of the core substrate 58, and the cable patterns 56 formed on the both side faces of the core substrate 58 are mutually electrically connected by the plated through-hole sections 52.

In the core substrate 58 of the present embodiment, the inner faces of the pilot holes 18 formed in the core section 10 are doubly coated with the plated layers 19 and the insulating films 21, and the insulating films 21 are exposed on the inner faces of the pilot holes 18. Therefore, even if voids are formed in the resin 20 and the voids make expanded parts 52b in the plated through-hole section 52 when the pilot holes 18 are filled with the resin 20, the insulating film 21 exists between the expanded parts 52b and the plated layer 19 so that short circuit between the plated through-hole sections 52 and the core section 10 can be prevented.

If voids are formed on the inner side faces of the pilot holes 18 when the pilot holes 18 are filled with the resin 20, the plated through-hole sections 52 will be electrically connected to the inner faces of the pilot holes 18 at positions corresponding to the voids. By forming the voids, the plated through-hole sections 52 will be electrically connected to the inner faces of the pilot holes 18. To solve this problem, forming voids in the resin 20 can be prevented by coating the inner faces of the pilot holes 18 with the plated layers 19. Further, even if voids are formed in the resin 20, the insulating films 21 are capable of securely and effectively insulating the plated through-hole sections 52 from the core section 10.

### (Steps of Producing Circuit Board)

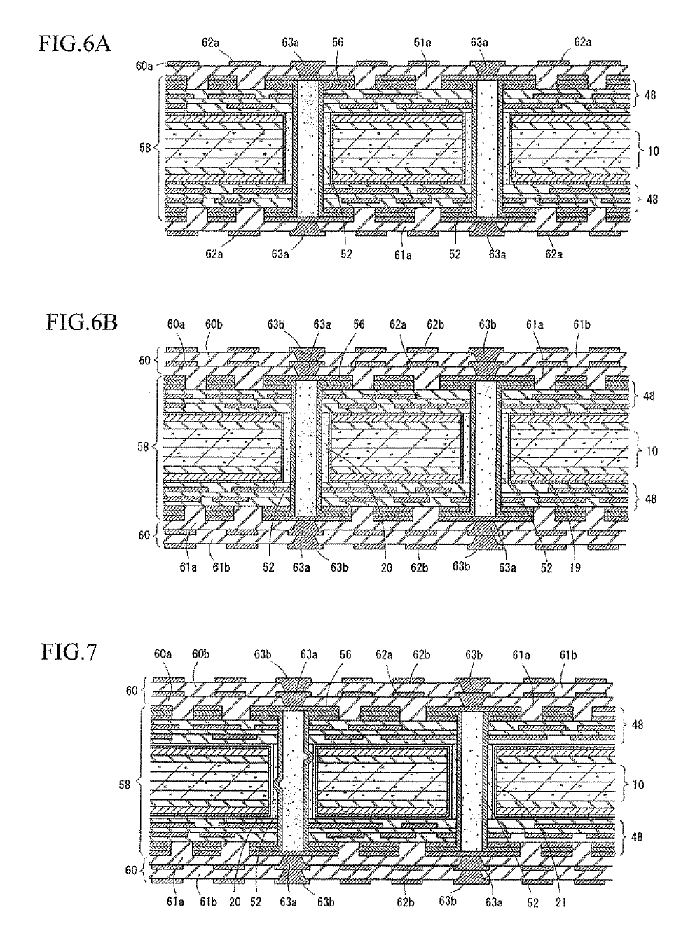

The circuit board can be produced by laminating the cable patterns on the both side faces of the core substrate 58 shown in FIG. 4C. FIGS. 6A and 6B show the steps of producing the circuit board, in which the cable patterns are laminating on the both side faces of the core substrate 58 shown in FIG. 4C.

The cable patterns can be laminated or layered on the both side faces of the core substrate 58 by, for example, a build-up method. In FIG. 6A, first build-up layers 60a are formed on the both side faces of the core substrate 58; in FIG. 6B, second build-up layers 60b are formed. In FIGS. 6A and 6B, two-layered build-up layers 60 are formed. Note that, number of layers in each of the build-up layers 60 may be optionally selected.

In FIG. 6A, each of the first build-up layers 60a includes: an insulating layer 61a; a cable pattern 62a formed on a surface of the insulating layer 61a; and vias 63a electrically connecting the lower cable pattern 56 to the upper cable pattern 62a. In FIG. 6B, each of second build-up layers 60b includes: an insulating layer 61b; a cable pattern 62b; and vias 63b.

The cable patterns 62a and 62b, which are included in the build-up layers 60 formed on the both side faces of the core substrate 58, are mutually electrically connected by the plated through-hole sections 52 and the vias 63a and 63b.

The steps of forming the build-up layers 60 will be explained.

Firstly, insulating layers 61a are formed on the both side faces of the core substrate 58 by laminating insulating resin films, e.g., epoxy film, and via holes, in which the vias 63a will be formed and in which the cable patterns 56 formed on the side faces of the core substrate 58 are exposed, are bored in the insulating layers 61a by laser means.

Next, the inner faces of the via holes are desmear-treated so as to roughen the inner faces thereof, and then the inner faces of the via holes and the surfaces of the insulating layers 61a are coated with copper layers by the electroless plating method.

The electroless-plated copper layers are coated with photoresist, and then resist patterns, in which parts of the electroless-plated copper layers which will be formed as the cable patterns 62a are exposed, are formed by optically exposing and developing the photoresist.

Further, the electrolytic plating method, in which the resist patterns are used as masks and in which the electroless-plated copper layers are used as electric power feeding layers, is performed so as to supply copper to the exposed parts of the electroless-plated copper layers for upraising the copper therein. In this step, the via holes are filled with copper supplied by the electrolytic plating method and the vias 63a are formed.

Next, the resist patterns are removed, and the exposed parts of the electroless-plated copper layers are etched and removed, so that cable patterns 62a are formed, in prescribed patterns, on the surfaces of the insulating layers 61a.

The second build-up layers 60b can be formed as well as the first build-up layers 60a. In each of the cable layers, the cable patterns 62a and 62b can be formed in optional patterns. Electrodes, to which semiconductor elements will be connected, or connecting pads, to which external connectors will be connected, are patterned in the outermost layers, and the outermost layers other than the exposed parts, e.g., electrodes, connecting pads, are coated with protection films. The exposed electrodes or connecting pads are plated with, for example, gold for protection.

FIG. 7 shows the circuit board, in which the build-up layers 60 are formed on the both side faces of the core substrate 58 shown in FIG. 5. The structures of the build-up layers 60 are similar to those shown in FIGS. 6A and 6B.

An example of the build-up method has been explained, but other build-up methods may be employed in the present invention. Further, other methods for forming the cable layers having the layered structures may be employed instead of the build-up method. In the present invention, the method of forming the cable layers having the layered structures is not limited to the build-up method.

The invention may be embodied in other specific forms without departing from the spirit of essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A core substrate,
comprising:
an electrically conductive core section having a pilot hole, through which a plated through-hole section is formed;
cable layers being respectively laminated on the both side faces of the core section;
a plated layer coating an inner face of the pilot hole; and
an insulating material filling a space between the plated layer and an outer circumferential face of the plated through-hole section.

2. The core substrate according to claim 1,
further comprising an insulating film coating the plated layer, which coats the inner face of the pilot hole.

3. The core substrate according to claim 1,
wherein the plated layer makes the inner face of the pilot hole smooth.

4. The core substrate according to claim 1,
wherein the plated layer encompasses electrically conductive accretions stuck on the inner face of the pilot hole.

5. The core substrate according to claim 1,
wherein the core section is composed of carbon fiber-reinforced plastic and formed into a flat plate by heating and pressurizing a plurality of prepregs including carbon fibers.

6. A method of producing a core substrate,
comprising the steps of:
forming a pilot hole in a substrate having an electrically conductive core section;
forming a plated layer on an inner face of the pilot hole;
filling the pilot hole, in which the plated layer has been formed, with an insulating material;
forming a through-hole in the pilot hole, which has been filled with the insulating material; and
forming a plated layer on an inner face of the through-hole so as to form a plated through-hole section.

7. The method according to claim 6,
wherein cable layers are integrally formed on the both side faces of the substrate after filling the pilot hole with the resin, and
the through-hole, which passes through the pilot hole, is formed in the substrate, on which the cable layers have been integrally formed.

8. The method according to claim 6,
wherein an insulating film is formed on the plated layer by an electrodeposition process, in which the plated layer is used as an electric power feeding layer, after forming the plated layer on the inner face of the through-hole by plating the substrate having the pilot hole.

9. The method according to claim 6,
wherein a plated layer, which makes the inner face of the pilot hole smooth, is formed when the substrate having the pilot hole is plated.

10. The method according to claim 6,
wherein a plated layer, which encompasses electrically conductive accretions stuck on the inner face of the pilot hole, is formed when the substrate having the pilot hole is plated.

11. The method according to claim 6,
wherein the core section is formed into a flat plate by the steps of: laminating a plurality of prepregs including carbon fibers; and heating and pressurizing the laminated prepregs.

12. A multi-layered circuit board,
comprising:
a core substrate including an electrically conductive core section having a pilot hole, through which a plated through-hole section is formed, cable layers being respectively laminated on the both side faces of the core section, a plated layer coating an inner face of the pilot hole, and an insulating material filling a space between the plated layer and an outer circumferential face of the plated through-hole section; and
a cable layer being laminated on the core substrate.
